(19) United States
(12) Patent Application Publication
(10) Pub. No.: US 2022/0200443 A1
(43) Pub. Date: Jun. 23, 2022

(54) Snubber Capacitor

(71) Applicant: ZF Friedrichshafen AG, Friedrichshafen (DE)

(72) Inventor: Wei Liu, Friedrichshafen (DE)

(21) Appl. No.: 17/557,799

(22) Filed: Dec. 21, 2021

(30) Foreign Application Priority Data
Dec. 22, 2020 (DE) 10 2020 216 473.8

(51) Int. Cl. H02M 1/34; H02M 7/00; H05K 1/02; H05K 1/18; H01G 4/30

(52) U.S. Cl. CPC H02M 1/34; H02M 7/003; H05K 2201/068; H05K 1/182; H01G 4/30; H05K 1/0271

(57) ABSTRACT

A snubber capacitor includes a first electrode, a second electrode and a capacitor core therebetween. A conductive first extraction element is electrically coupled to the first electrode and covers at least a part of the first electrode and a part of the capacitor core. A conductive second extraction element is electrically coupled to the second electrode and covers at least a part of the second electrode and another part of the capacitor core. The first extraction element is insulated from the second extraction element.

### FIELD OF THE INVENTION

The invention relates generally to a snubber capacitor, in particularly a snubber capacitor provided inside a power module.

### CROSS-REFERENCE TO RELATED APPLICATION

The present application is related and has right of priority to German Patent Application No. 102020216473.8 filed in the German Patent Office on Dec. 22, 2020, which is incorporated by reference in its entirety for all purposes.

### BACKGROUND OF THE INVENTION

Power devices (WBG (wide bandgap) semiconductors, such as SiC, GaN) are becoming more and more popular in applications where fast and efficient switching is required, such as power supply applications. In addition, the power devices are usually interfered with by stray inductance of a power module package and surrounding circuits, and fast switching capability of the power devices causes high voltage differentials over time (dv/dt), which results in large surge voltage and EMI (Electromagnetic Interference) noise between drain and source terminals of the power devices when switching off.

In order to smooth the voltage surge and reduce the noise, a snubber capacitor Cc is added, as shown in FIG. 1. Referring to FIG. 2, two voltage waveforms respectively with and without a snubber capacitor are illustrated. As shown by the dash line, the voltage surge is smoothed by the snubber capacitor. Thus, snubber capacitors are standard elements in the WBG semiconductor applications.

Referring now to FIG. 3, a conventional inverter design is shown schematically in a block diagram. The inverter includes an AC connector 101, a DC connector 102, a power module 103 with multiple power devices 1031, such as WBG power devices, and a snubber capacitor 104 adjacent to the power module 103. The snubber capacitor 104 needs to be provided as close to the power devices 1031 as possible. In the conventional inverter, the snubber capacitor is only provided adjacent to part of the power devices, thus the smoothing effect of the snubber capacitor is limited.

Besides, a MLCC (Multi-layer Ceramic Capacitor) is commonly used in the conventional inverter design for the suitable capacitance value of the MLCC. A MLCC includes two external electrodes and a capacitor core with dielectric and internal electrodes. Referring to FIG. 4, a MLCC 104 is soldered onto a copper pattern layer 114 by solder material 6 and there is a gap 118 under the MLCC. A thermal resin 112 is provided between the copper pattern layer 114 and a Pin-Fin cooling member 110 (a person skilled in the art shall understand there is an insulative material between the copper pattern and the cooling member, in this case, the thermal resin 112 is used as the insulative material). In this design, the heat generated by the MLCC 104 can only be dissipated through the solder material 6 which results in an undesirable heat conduction efficiency. In some cases, the snubber capacitors are even burnt out under severe thermal conditions.

### BRIEF SUMMARY

In order to improve the thermal condition of the snubber capacitor and enhance the smoothing effect, a snubber capacitor is disclosed. The snubber capacitor includes a first electrode, a second electrode and a capacitor core therebetween, a conductive first extraction element electrically coupled to the first electrode and covering at least a part of the first electrode and a part of the capacitor core, a conductive second extraction element electrically coupled to the second electrode and covering at least a part of the second electrode and another part of the capacitor core, wherein the first extraction element is electrically insulated from the second extraction element. With this design, the extraction elements enlarge the contact area between the snubber capacitor and elements coupled to the snubber capacitor (such as external connectors of an inverter, circuit patterns of a conductive layer of a power module). Thus, the heat dissipation of the snubber capacitor is improved.

According to another example aspect of the invention, the end surface of the first electrode coupled to the first extraction element is opposite to the end surface of the second electrode coupled to the second extraction element.

According to another example aspect of the invention, the sidewall of the capacitor core covered by the first extraction element is opposite to the sidewall of the capacitor core covered by the second extraction element.

According to another example aspect of the invention, the sidewall of the capacitor core covered by the first extraction element is adjacent to the sidewall of the capacitor core covered by the second extraction element. This snubber capacitor can be provided near the power elements of a power module to smooth the voltage surge and decrease the EMI noise.

According to another example aspect of the invention, the first extraction element and the second extraction element are both L-shaped. With these extraction elements, the snubber capacitor can be provided inside a power module either vertically or horizontally.

According to another example aspect of the invention, at least one of the first extraction element and the second extraction element includes a base portion and two extended portions extending from the base portion along the longitudinal direction of the snubber capacitor, the two extended portions extending parallel to the two adjacent sidewalls of the capacitor core, respectively. In an alternative example embodiment, at least one of the first extraction element and the second extraction element includes a base portion and two extended portions extending from the base portion along the longitudinal direction of the snubber capacitor, the two extended portions extending parallel to the opposite sidewalls of the capacitor core, respectively. Snubber capacitors with adjacent extended portions are mainly used as inner snubber capacitors inside the power module, while snubber capacitors with opposite extended portions are used outside the power module. With these extraction elements, the heat-dissipating area of the snubber capacitor is increased, which improves the thermal effect of the snubber capacitor. Besides, the snubber capacitor is affected less by the stress change caused by temperature variations.

According to another example aspect of the invention, the first extraction element is soldered/sintered to the first electrode, and/or, the second extraction element is soldered/sintered to the second electrode.

According to another example aspect of the invention, the first extraction element is ultrasonically soldered to the first electrode, and/or, the second extraction element is ultrasonically soldered to the second electrode.

According to another example aspect of the invention, the first extraction element is sintered to the first electrode by silver, and/or, the second extraction element is sintered to the second electrode by silver.

According to another example aspect of the invention, a power module is disclosed. The power module includes the snubber capacitor described above, the snubber capacitor is provided inside a power module, the power module includes at least one power semiconductor element, a first conductive layer and a second conductive layer configured to sandwich the power semiconductor element therebetween, the first extraction element is electrically coupled to the first conductive layer, the second extraction element is electrically coupled to the second conductive layer, the thermal expansion coefficient of the first extraction element is between that of the first conductive layer and that of the first electrode, the thermal expansion coefficient of the second extraction element is between that of the second electrode and that of the second conductive layer. With this design, thermal transition from the electrodes to the conductive layers is gradual enough to avoid an uneven distribution of stress, thus the snubber capacitor could be well fixed in the power module. Besides, the contact area between the snubber capacitor and the conductive layers is large enough to achieve an improved heat dissipation.

According to another example aspect of the invention, the snubber capacitor is positioned adjacent to the power semiconductor element.

According to another example aspect of the invention, the operating temperature of the power module is negative forty degrees Celsius and one hundred and fifty degrees Celsius (−40° C.˜150° C.). The voltage between the first conductive layer and the second conductive layer is between three hundred volts and eight hundred volts (300V˜800V). The current between the first conductive layer and the second conductive layer is between one hundred amps and one thousand amps (100 A˜1000 A).

According to another example aspect of the invention, the snubber capacitor is a MLCC.

Other aspects and advantages of the embodiments will become apparent from the following detailed description taken in conjunction with the accompanying drawings which illustrate, by way of example, the principles of the described embodiments.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by on skilled in the art without departing from the spirit and scope of the described embodiments.

FIG. 1 illustrates a power supply circuit using power devices.

FIG. 2 illustrates two voltage waveforms respectively with and without a snubber capacitor.

FIG. 3 illustrates a diagram of a conventional inverter, wherein a snubber capacitor is provided adjacent to the power module.

FIG. 4 illustrates a cross sectional view of a snubber capacitor arrangement with a Pin-Fin cooling member.

FIG. 5 illustrates a perspective view of a snubber capacitor in accordance with the first example embodiment of the invention.

FIG. 6 illustrates a perspective view of the extraction elements of the example snubber capacitor in FIG. 5.

FIG. 7 illustrates a perspective view of a snubber capacitor in accordance with the second example embodiment of the invention.

FIG. 8 illustrates another perspective view of the snubber capacitor in accordance with the second example embodiment of the invention.

FIG. 9 illustrates a perspective view of the extraction elements of the example snubber capacitor in FIG. 7.

FIG. 10 illustrates another perspective view of the extraction elements in accordance with the second example embodiment of the invention.

FIG. 11 illustrates a power module with double-sided cooling device in accordance with the second example embodiment of the invention.

FIG. 12 illustrates another perspective view of the power module.

FIG. 13 illustrates a perspective view of a snubber capacitor in accordance with the third example embodiment of the invention.

FIG. 14 illustrates a perspective view of the extraction elements of the example snubber capacitor in FIG. 13.

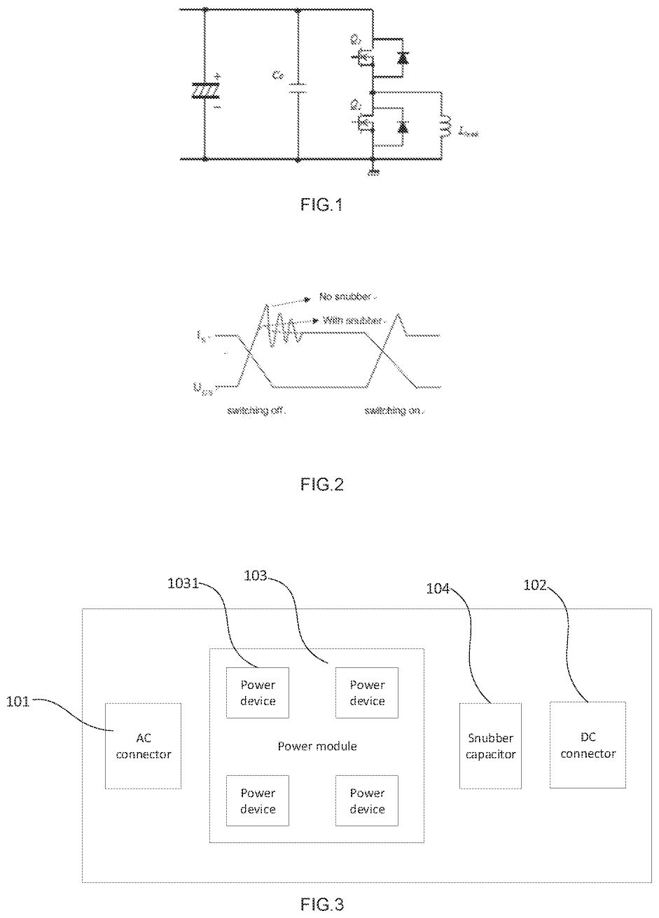

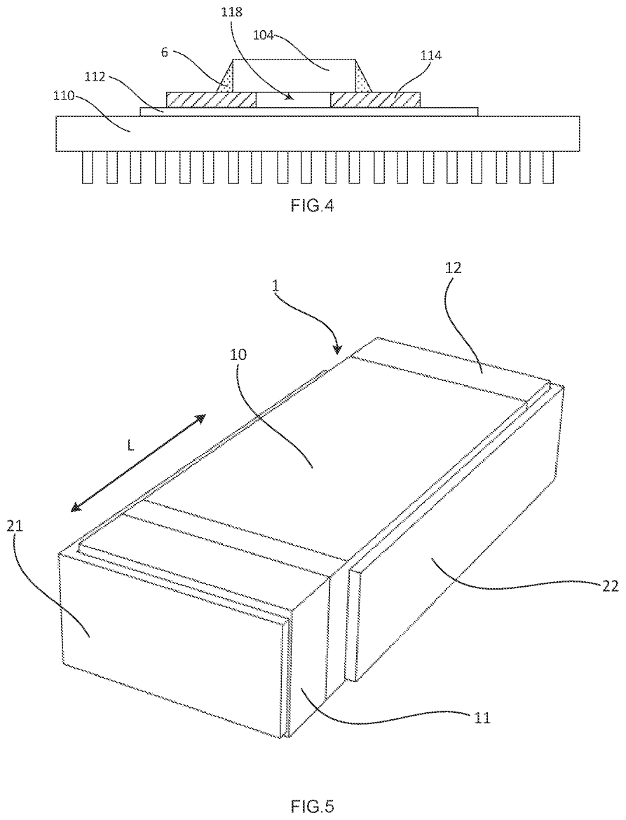

### DETAILED DESCRIPTION OF THE EMBODIMENTS

Reference will now be made to embodiments of the invention, one or more examples of which are shown in the drawings. Each embodiment is provided by way of explanation of the invention, and not as a limitation of the invention. For example, features illustrated or described as part of one embodiment can be combined with another embodiment to yield still another embodiment. It is intended that the present invention include these and other modifications and variations to the embodiments described herein.

Referring now to the drawings, example embodiments of the invention are described in detailed. In this invention, the snubber capacitors of different embodiments are mainly used in Auto industry, such as in a power module of an inverter, or in an inverter of an electric vehicle. The snubber capacitors are provided inside a power module or adjacent to a power module. Unlike in PCB application, the operation conditions of the power modules are much stricter. For example, the operating temperature of the power modules is in the range of negative forty degrees Celsius and one hundred and fifty degrees Celsius (−40° C.˜150° C.). The voltage between the first conductive layer (representing positive polarity) and the second conductive layer (representing negative polarity) is between three hundred volts and eight hundred volts (300V˜800V). The current between the first conductive layer and the second conductive layer is between one hundred amps and one thousand amps (100 A˜1000 A). Therefore, to meet the above demands, the influence of temperature on the capacitors must be taken into consideration.

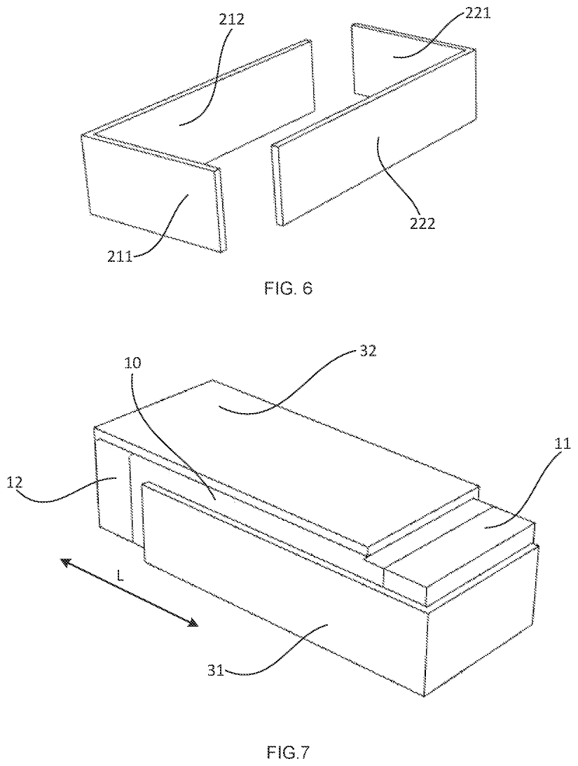

Referring first to FIG. 5 and FIG. 6, a snubber capacitor 1 includes a first electrode 11, a second electrode 12 and a capacitor core 10 therebetween. The snubber capacitor further include a conductive first extraction element 21 and a conductive second extraction element 22. The first extraction element 21 is electrically coupled to the first electrode 11 and covers at least a part of the first electrode 11 and a part of the capacitor core 10, the second extraction element 22 is electrically coupled to the second electrode 12 and covers at least a part of the second electrode 12 and another part of the capacitor core 10. In order to prevent a short-circuit, the first extraction element 21 is electrically insulated from the second extraction element 22. For example, the shortest distance between the first extraction element 21 and the second extraction element 22 in the longitudinal direction (L) of the snubber capacitor is at least one millimeter (1 mm).

Referring mainly to FIG. 6, the first extraction element 21 and the second extraction element 22 are both L-shaped. The first extraction element 21 includes a base portion 211 and an extended portion 212 extending from the base portion 211 along the longitudinal direction (L) of the snubber capacitor, and the second extraction element 22 includes a base portion 221 and an extended portion 222 extending from the base portion 221 along the longitudinal direction of the snubber capacitor. Taking the first extraction element 21 as an example, the base portion 211 is perpendicular to the extended portion 212, the first electrode 11 is coupled to and covered by the base portion 211, and one sidewall of the capacitor core 10 is partially covered by the extended portion 212. The end surface of the first electrode 11 coupled to the first extraction element 21 is opposite to the end surface of the second electrode 12 coupled to the second extraction element 22. The sidewall of the capacitor core covered by the first extraction element is opposite to the sidewall of the capacitor core covered by the second extraction element.

In this example embodiment, the first extraction element 21 is soldered to the first electrode 11, and the second extraction element 22 is soldered to the second electrode 22. More particularly, the extraction elements 21,22 are ultrasonically soldered to the electrodes. In other preferred example embodiments, the extraction elements 21,22 can be sintered to the electrodes 11,12 by silver.

In power electronics applications, for example, the snubber capacitor can be applied in an inverter. The snubber capacitor is provided near the power module to smooth the voltage surge during the switching of the power semiconductor elements inside the power module. With the help of the extraction elements, the snubber capacitor can be fixed on a copper pattern layer steadily or securely. Meanwhile the thermal effect is also improved by the increased heat-dissipating area. In this application, the sidewall of the capacitor core covered by the first extraction element is adjacent to the sidewall of the capacitor core covered by the second extraction element.

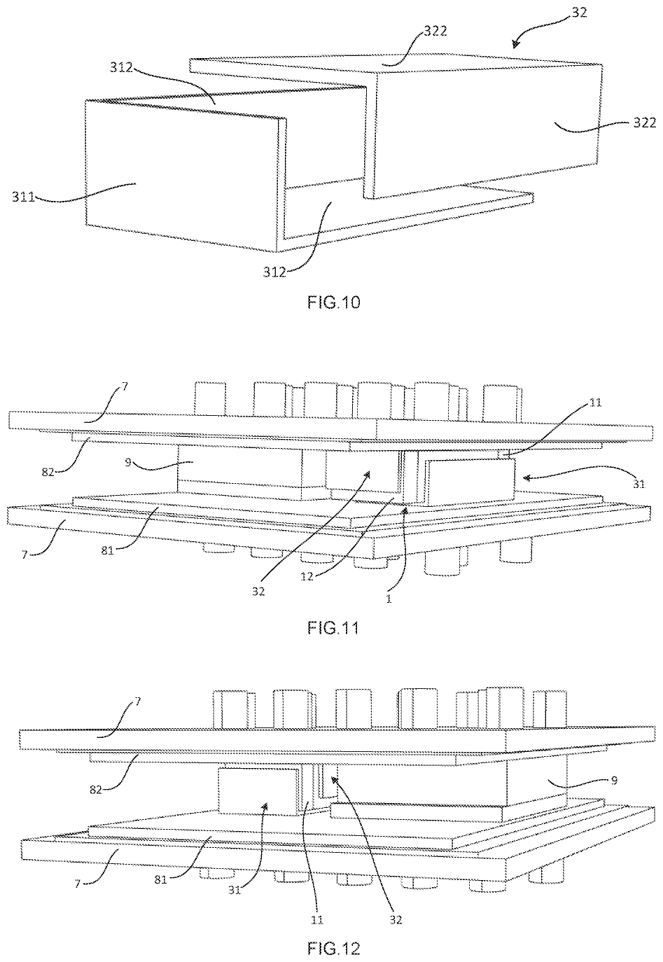

Referring now to FIG. 7-FIG. 10, a snubber capacitor in accordance with the second example embodiment of the invention is illustrated. Instead of L-shaped extraction element, each of the first extraction element 31 and the second extraction element 32 includes a base portion 311,321 and two extended portions 312,322 extending from the base portion 311,321 along the longitudinal direction (L) of the snubber capacitor, the two extended portions 312,322 extending parallel to adjacent sidewalls of the capacitor core 10, respectively.

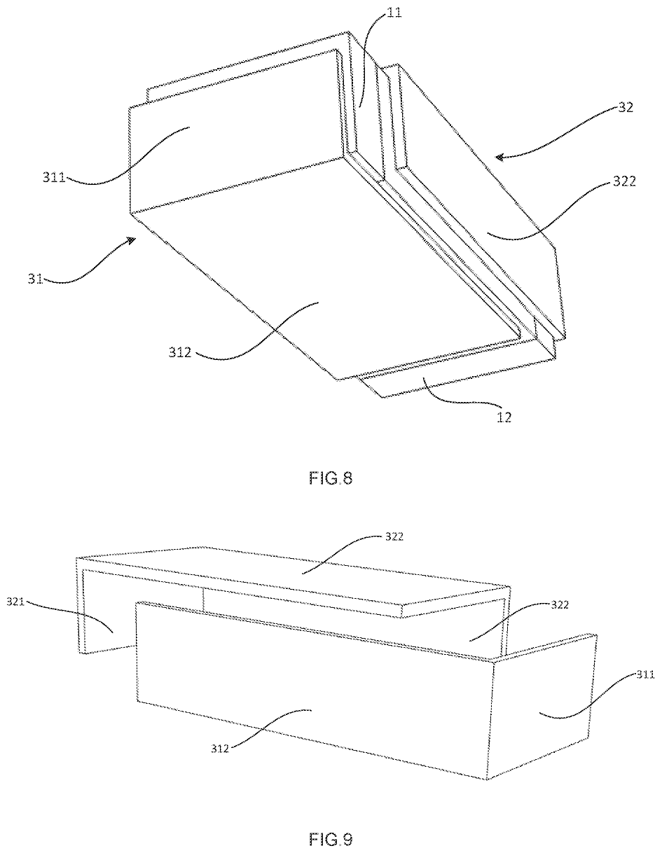

In some applications, the snubber capacitor (as shown in FIG. 7-FIG. 8) is a MLCC provided inside a power module. Referring now to FIG. 11-FIG. 12, the power module includes at least one power semiconductor element 9 (such as SiC device), a first conductive layer 81 and a second conductive layer 82 configured to sandwich the power semiconductor element 9 therebetween. Both the first conductive layer 81 and the second conductive layer 82 are coupled to a cooling device 7 with Pin-Fin structure. The first extraction element 31 is electrically coupled to the first conductive layer 81 and the second extraction element 32 is electrically coupled to the second conductive layer 82. The snubber capacitor 1 is provided adjacent to the power semiconductor element 9 such that the voltage surge caused during the switching on and off of the power semiconductor elements is smoothed and the EMI noise is decreased. The thermal expansion coefficient of the first extraction element 31 is between that of the first conductive layer and that of the first electrode 11, the thermal expansion coefficient of the second extraction element 32 is between that of the second electrode 12 and that of the second conductive layer. Therefore, these extraction elements provide a gradual thermal transition from the electrodes to the busbars (coupled to the first and second conductive layers) of the power module and prevent an uneven distribution of stress, and thus the snubber capacitor is well fixed, even inside the power module. With this design, uneven distribution of stress in the snubber capacitor due to the different thermal effect is avoided, and thus the life span of the snubber capacitor is extended.

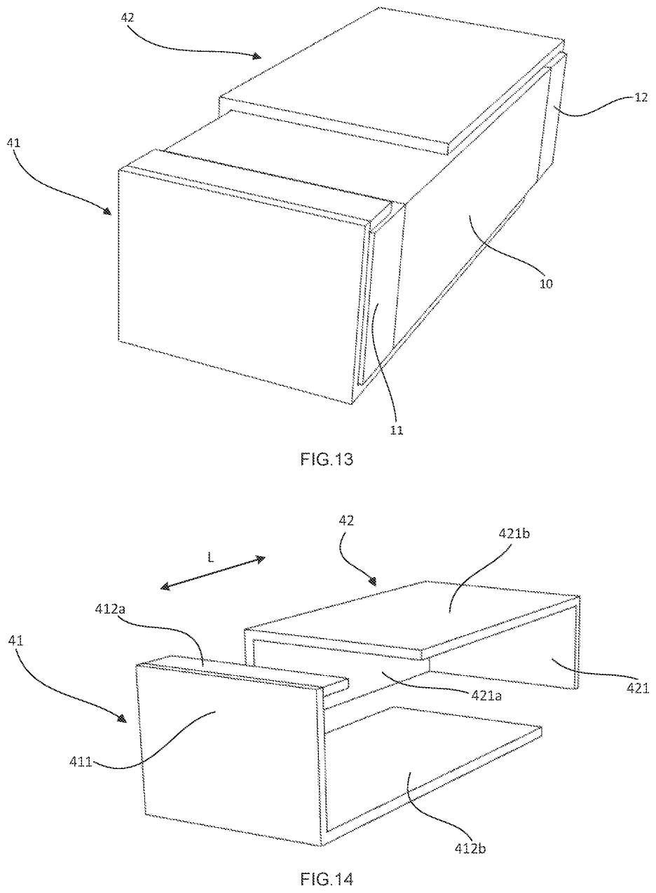

Referring now to FIG. 13 and FIG. 14, a snubber capacitor and extraction elements according to the third example embodiment are shown. The first extraction element 41 includes a base portion 411 and two extended portions 412a, 412b extending from the base portion 411 along the longitudinal direction of the snubber capacitor. One extended portion 412a extends parallel to the top surface of the capacitor core, and the other extended portion 412b extends parallel to the bottom surface of the capacitor core. The second extraction element 42 includes a base portion 421 and two extended portions 421a, 421b extending from the base portion 421 along the longitudinal direction of the snubber capacitor. The extended portions 421a, 421b cover the adjacent sidewalls of the capacitor core. The distance between the extended portion 412a and the extended portion 421b along the longitudinal direction is at least one millimeter (1 mm).

A number of alternative structural elements have been suggested for the preferred embodiment. Thus, while the invention has been described with reference to specific embodiments, the description is illustrative of the invention and is not to be construed as limiting the invention. Various modifications and applications may occur to those skilled in the art without departing from the true spirit and scope of the invention as defined by the appended claims.

Modifications and variations can be made to the embodiments illustrated or described herein without departing from the scope and spirit of the invention as set forth in the appended claims. In the claims, reference characters corresponding to elements recited in the detailed description and the drawings may be recited. Such reference characters are enclosed within parentheses and are provided as an aid for reference to example embodiments described in the detailed description and the drawings. Such reference characters are provided for convenience only and have no effect on the scope of the claims. In particular, such reference characters are not intended to limit the claims to the particular example embodiments described in the detailed description and the drawings.

1-13: (canceled)

14. A snubber capacitor, comprising:
a first electrode;
a second electrode;
a capacitor core between the first and second electrodes;
a conductive first extraction element electrically coupled to the first electrode and covering at least a portion of the first electrode and a first portion of the capacitor core; and
a conductive second extraction element electrically coupled to the second electrode and covering at least a portion of the second electrode and a second portion of the capacitor core,
wherein the first extraction element is electrically insulated from the second extraction element.

15. The snubber capacitor of claim 14, wherein a first end surface of the first electrode coupled to the first extraction element is opposite to a second end surface of the second electrode coupled to the second extraction element.

16. The snubber capacitor of claim 14, wherein a first sidewall of the capacitor core covered by the first extraction element is positioned opposite a second sidewall of the capacitor core covered by the second extraction element.

17. The snubber capacitor of claim 14, wherein a first sidewall of the capacitor core covered by the first extraction element is positioned adjacent a second sidewall of the capacitor core covered by the second extraction element.

18. The snubber capacitor of claim 14, wherein the first extraction element and the second extraction element are both L-shaped.

19. The snubber capacitor of claim 14, wherein:
at least one of the first extraction element and the second extraction element comprises a base portion and two extended portions extending from the base portion along a longitudinal direction of the snubber capacitor, the two extended portions extending parallel to two adjacent sidewalls of the capacitor core, respectively; or
at least one of the first extraction element and the second extraction element comprises a base portion and two extended portions extending from the base portion along the longitudinal direction of the snubber capacitor, the two extended portions extending parallel to two opposite sidewalls of the capacitor core, respectively.

20. The snubber capacitor of claim 14, wherein one or both of:
the first extraction element is soldered or sintered to the first electrode; and
the second extraction element is soldered or sintered to the second electrode.

21. The snubber capacitor of claim 20, wherein one or both of:
the first extraction element is ultrasonically soldered to the first electrode; and
the second extraction element is ultrasonically soldered to the second electrode.

22. The snubber capacitor of claim 20, wherein one or both of:
the first extraction element is sintered to the first electrode by silver; and
the second extraction element is sintered to the second electrode by silver.

23. A power module, comprising:
the snubber capacitor of claim 14 provided inside the power module;
at least one power semiconductor element;
a first conductive layer and a second conductive layer configured to sandwich the power semiconductor element therebetween,
wherein the first extraction element is electrically coupled to the first conductive layer, and the second extraction element is electrically coupled to the second conductive layer, and
wherein a thermal expansion coefficient of the first extraction element is between that of the first conductive layer and that of the first electrode, and a thermal expansion coefficient of the second extraction element is between that of the second electrode and that of the second conductive layer.

24. The power module of claim 23, wherein the snubber capacitor is positioned adjacent the power semiconductor element.

25. The power module of claim 23, wherein one or more of:
an operating temperature of the power module is in a range of −40° C.˜150° C.;
an operating voltage between the first conductive layer and the second conductive layer is in a range of 300V-800V; and
an operating current between the first conductive layer and the second conductive layer is in a range of 100 A-1000 A.

26. The power module of claim 23, wherein the snubber capacitor is a multi-layer ceramic capacitor.
